(19) United States
(12) Patent Application Publication
(10) Pub. No.: US 2006/0045283 A1
(43) Pub. Date: Mar. 2, 2006

(54) Method And Related Apparatus For Generating Audio Reverberation Effect

(76) Inventors: Sen Lin, Taipei Hsien (TW); Longmei Zhang, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/160,777

(22) Filed: Jul. 8, 2005

(30) Foreign Application Priority Data
Aug. 26, 2004 (TW) 093125514

(51) Int. Cl. H03G 3/00; G10H 1/02

(52) U.S. Cl. 381/63; 84/630

(57) ABSTRACT

Method and related apparatus for generating an output signal with audio reverberation effect according to an input signal. In the invention, a constant echo interval is chosen, then a plurality of delay signals, which are delayed signals of the input signal, are generated such that a delay signal and its adjacent delay signal has a delay time equal to the echo interval; and a quantity of the delay signals is adaptively determined according to how many echo intervals are covered in an early reflection portion of the reverberation effect. These delay signals are low-pass filtered for forming the early reflection portion of the output signal, and comb filtering is performed on these delay signals for forming a late reverberation portion of the output signal.

### BACKGROUND OF INVENTION

1. Field of the Invention

The present invention relates to a method and related apparatus for generating an audio reverberation effect, and more particularly, to a method and related apparatus which adaptively generate a plurality of delay signals according to how many echo intervals are covered in an early reflection period for filling the early reflection portion with the audio reverberation effect.

2. Description of the Prior Art

Music can soothe people's hearts, and is an important part of people's lives. According to research, harmonious music relates not only to characteristics of the instruments, and the skill levels of the players and the singers, but also to the surroundings in which the music is played. For an audience, the music will be more appealing if it is played in a well designed music hall. A special sound effect is called audio reverberation effect where the music resonates and reverberates in a music hall. Currently, music can be played by electronic devices, such as a CD player, an MP3 player, or a multi-media computer, among many other devices. However, these devices cannot play music as if it were in a concert hall to allow the users of these devices to enjoy the audio reverberation effect. Considering space and social constraints, users typically only listen to the music with earphones. Technology companies have already started to study methods that can produce an audio reverberation effect, and have tried to add the audio reverberation effect to the audio signals by using signal processing, allowing the users to enjoy the audio reverberation effect without actually going to a concert hall.

In order to simulate a sound (music) with the audio reverberation effect in a specified space, the prior art usually uses light-tracing method or other complicated algorithms to simulate the music being emitted in a specified space in order to generate the audio reverberation effect. However, such methods require heavy computational power and large memory resources for signal processing, and as a result, the audio reverberation effect cannot be generated in a low-cost and efficient way.

### SUMMARY OF INVENTION

It is therefore an objective of the claimed invention to provide a compact, low-cost and highly efficient method for generating an audio reverberation effect, in order to solve the disadvantages of the prior art.

One of the factors forming the audio reverberation effect is the sound propagating along different paths in a specified space. In a specified closed space, a sound travels along different paths, which may be reflected between different walls, and finally arrives at the destination or so called audience. Because different paths have different lengths, the sounds that go along different paths will arrive at the destination with different delay times. Combining these sounds at the destination will make the audience feel a certain amount of the audio reverberation effect, especially the early reflection portion of the audio reverberation effect. However, according to the study of the present invention, the human ear can only couple adjacent delay sounds which have a constant time interval between them. This time interval is called an echo interval in the present invention; the echo interval is typically less than 10 milliseconds, for example 8 milliseconds (ms). In other words, if one sound combines with a delayed sound which has a delay time interval longer than the echo interval, human hearing will process these sounds as two different fragmented sounds, and cannot feel the audio reverberation effect. Conversely, if a sound combines with a delayed sound which has a delay time interval shorter than the echo interval, human hearing will treat these sounds as the same single high pitch sound, and cannot feel the audio reverberation effect as well. Defining the echo interval as a benchmark, since delayed sounds having a longer or shorter delay time interval do not contribute to the audio reverberation effect, the present invention only uses delayed sounds which have a delay time interval equal to the echo interval to implement the audio reverberation effect, especially the early reflection portion thereof.

More specifically, when the present invention adds the audio reverberation effect to an input signal for generating a corresponding output signal, a plurality of delay signals, which are delay signals of the input signal, are generated such that each delay signal and its adjacent delay signal have a delay time equal to the echo interval; and a quantity of the delay signals is adaptively determined according to how many echo intervals are covered in an early reflection period of the audio reverberation effect. For example, when the present invention simulates the audio reverberation effect of a large room having high reflectivity walls, because the early reflection portion will be longer in this room, there are more echo intervals covered in the early reflection period, and the present invention can adaptively generate more delay signals to form the early reflection portion. Conversely, when in a small room having low reflectivity walls, there are fewer echo intervals covered in the early reflection period, and so to simulate this, the present invention can adaptively generate fewer delay signals to form the early reflection portion. With regard to the late reverberation portion, the present invention can use comb filters to implement the late reverberation portion of the audio reverberation effect. The late reverberation portion can also be attained by currently available late reverberation techniques.

The present invention only needs to generate delay signals, for which the delay time interval is equal to the echo interval, to produce the audio reverberation effect; therefore, the present invention can be implemented by using delays without requiring intensive computing and memory resources, such that it is a low cost and high efficiency way to achieve the audio reverberation effect.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a perspective diagram showing a sound being emitted in a space.

FIG. 2 is a time-domain impulse response diagram according to the audio reverberation effect of the sound of FIG. 1.

FIG. 3 is a function block diagram of an audio circuit according to the present invention.

FIG. 4 is a time-domain impulse response diagram according to the delay module of FIG. 3.

FIG. 5 is a flow chart showing the implementation of the audio reverberation effect of the present invention.

### DETAILED DESCRIPTION

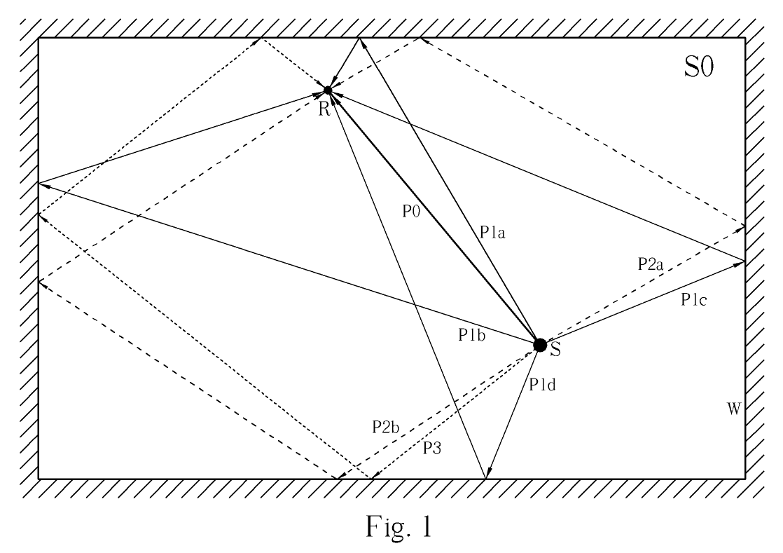

Please refer to FIG. 1, which shows several paths of a sound going to a destination R from a source S in a specified space S0. When emitted from the source S, the sound goes to the destination R via many different paths; for example, the sound can go directly to the destination R along path P0, or it can arrive at the destination R after being reflected once by the wall W of the space S0, such as by paths P1a, P1b, P1c and P1d. Of course, the sound can also arrive at the destination R after being reflected multiple times by the wall W, such as by paths P2a, P2b, or P3 etc. Because these paths P0, P1a to P1d, P2a, P2b, P3, and so on, have different lengths, the sound will arrive at the destination R at different times by the different paths. For example, when a sound is emitted from the source S, the sound which travels by path P0 will arrive at the destination R first because P0 is the shortest path; the sounds going along paths P1a to P1d will arrive later with a bigger decay because these paths are longer, and the sound loses some energy when it is reflected by the wall W; for the same reason, the sound will arrive much later with a much bigger decay if via paths P2a or P2b, and so on. In other words, the sound received at the destination is the combination of sounds with different arrival times (or different delay times) and different decay levels; as a result, the destination or audience will feel the audio reverberation effect.

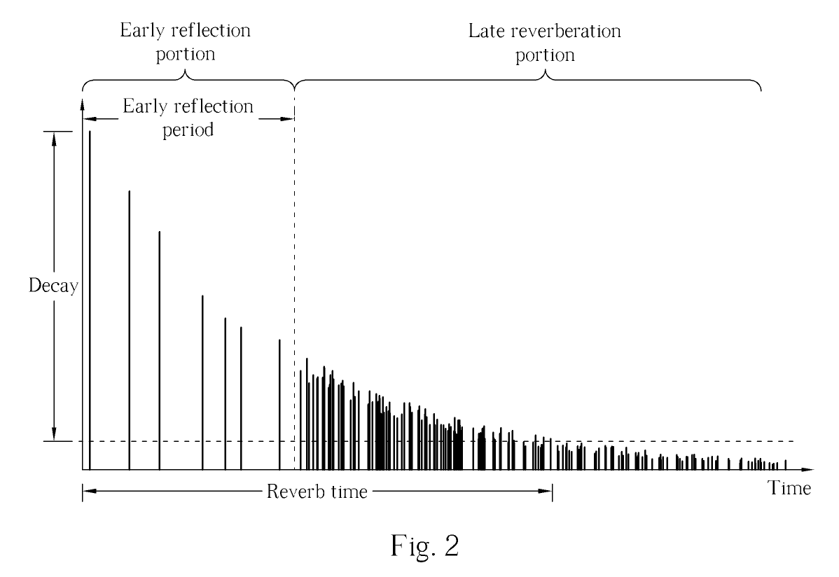

To further demonstrate the audio reverberation effect, please refer to FIG. 2 in combination with FIG. 1. Continuing the illustration of FIG. 1, if treating the sound emitted from the source S as an input signal, and treating the sound received at the destination R as an output signal, the time-domain impulse response between these two input/output signals will be as shown in FIG. 2. The horizontal axis of FIG. 2 represents time, and the vertical axis represents the magnitude of the response. As known by those skilled in the art, the impulse response shown in FIG. 2 is the sum of the different delay signals, which have different decay levels, with the input signal, and combination of these signals forms the output signal with the audio reverberation effect. As shown in FIG. 2, the audio reverberation effect can be divided into two portions, an early reflection portion and a late reverberation portion. The early reflection portion corresponds to the sounds that arrive at the destination R earlier, such that the impulse responses of this portion are stronger (having smaller decay), and the arriving rate, which is the number of sounds arriving at the destination R in a unit time, is lower, wherein the impulse responses are fewer and more separated from each other. Conversely, the late reverberation portion corresponds to the sounds that arrive at the destination R later; the arriving rate in this portion is higher, the impulse responses are much closer to each other, and the decay is bigger. Eventually, the signals of the late reverberation portion will decay to a level that the human ear cannot hear. The length of time where the impulse response has decayed to a certain level from the beginning, for example a 60 dB decay of the original magnitude, is called the reverb time. As shown in FIG. 2, a well-designed music hall has a reverb time of 1.5 to 2 seconds. The time where the early reflection portion exists is called an early reflection period.

The audio reverberation effect corresponds to factors comprising: the size and shape of the space S0, positions of the source S and the destination R, decoration in the space S0, reflection characteristics of the wall W (some wall materials are good for reflecting sounds, and some are good for absorbing sounds), characteristics of the air in the space S0 (it may absorb the energy of the sound), and so on. All of these factors may affect the audio reverberation effect; for example, they may change the length of the early reflection period and the reverb time and so forth. In addition, the wave-transmission characteristics of the sound are factors, for example, if there are obstacles in the space S0, an obstacle of a certain size may totally block or reflect the sound; but with an obstacle of another size, the sound could diffract and pass through it without being totally blocked or reflected. In addition, sounds of different frequencies have different reflection and transmission characteristics, which may also affect the audio reverberation effect. To simulate the audio reverberation effects corresponding to the above factors, the prior art usually uses many complicated signal processing techniques, ray-tracing methods, or other computationally-intensive algorithms, causing the implementation of the audio reverberation effect to require more computing and memory resources and thus to have higher cost and lower efficiency.

However, according to the research of the present invention, the audio reverberation effect can be achieved simply. The audio reverberation effect simulates the sounds in a specified space for the audience, however there are limitations of human hearing. Generally, human hearing can only detect a delay sound which has a constant time interval between it and its adjacent delay sound, this time interval being called an echo interval in the present invention; this time interval should be less than 10 milliseconds, for example 8 milliseconds (ms). In other words, if one sound combines with a delay sound for which the delay time interval is longer than the echo interval, the human ear will treat these sounds as two different fragmented sounds, and thus do not feel the audio reverberation effect. In contrast, if a sound combines with a delay sound for which the delay time interval is shorter than the echo interval, the human ear will treat these sounds as the same single high-pitched sound, and thus again cannot feel the audio reverberation effect. Defining the echo interval as a benchmark, since delay sounds having a longer or shorter delay time interval cannot contribute to the audio reverberation effect, the present invention only uses the delay sounds for which the delay time interval is equal to the echo interval to implement the audio reverberation effect, especially the early reflection portion thereof. In other words, when adding the audio reverberation effect to an input signal to generate a corresponding output signal, a plurality of delay signals, which are delay signals of the input signal, are generated such that each delay signal and its adjacent delay signal have a delay time equal to the echo interval; and a quantity of the delay signals is adaptively determined according to how many echo intervals exist in an early reflection period of the audio reverberation effect. According to the combination of these delay signals, the present invention generates the early reflection portion of the audio reverberation effect.

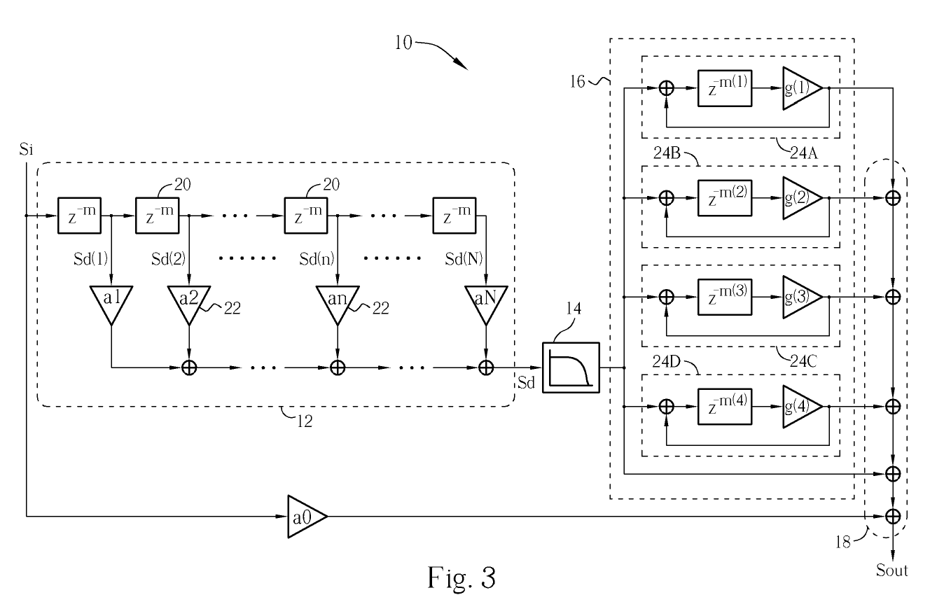

Please refer to FIG. 3, which shows a function block diagram of an audio circuit 10 according to the present invention. Based on the techniques described above, it is feasible to attain the audio reverberation effect by using the audio circuit 10. The audio circuit 10 performs signal processing on an electrical input signal Si to generate an output signal Sout, which exhibits the audio reverberation effect. The audio circuit 10 comprises a delay module 12, a low pass filter 14, a late reverberation module 16, and an adder module 18. Both the delay module 12 and the low pass filter 14 are for generating the early reflection portion of the audio reverberation effect; the late reverberation module 18 is for generating the late reverberation portion; the adder module 18 sums the early reflection portion and the late reverberation portion to generate the output signal Sout for creating the audio reverberation effect.

According to the techniques described above, the early reflection portion only keeps the delay signals for which the delay time interval is equal to the constant echo interval. Therefore a serial plurality of delays 20 are provided in the delay module 12 of the audio circuit 10. Each delay 20 separately delays a signal for one echo interval, and each output signal of the delays 20 is separately multiplied by different decay factors, a1 to aN, while passing through the multipliers 22. Next, these signals are combined to form the signal Sd. In other words, the first delay delays the input signal Si for one echo interval to form a delay signal Sd(1), the second delay delays the delay signal Sd(1) for one echo interval again to form a delay signal Sd(2), and so on. Overall, the delay module 12 generates the signal Sd, which is equal to:
a1×Sd(1)+a2×Sd(2)+ . . . +an×Sd(n)+ . . . +aN×Sd(N)
wherein the quantity of delays, which is N, is adaptively determined according to how many echo intervals exist in an early reflection portion. When simulating the audio reverberation in a bigger space, because the early reflection period is longer, the present invention adaptively uses more delays 20 in the delay module 12. On the other hand, when simulating an audio reverberation effect with a shorter early reflection period, the present invention adaptively uses fewer delays 20 in the delay module 12.

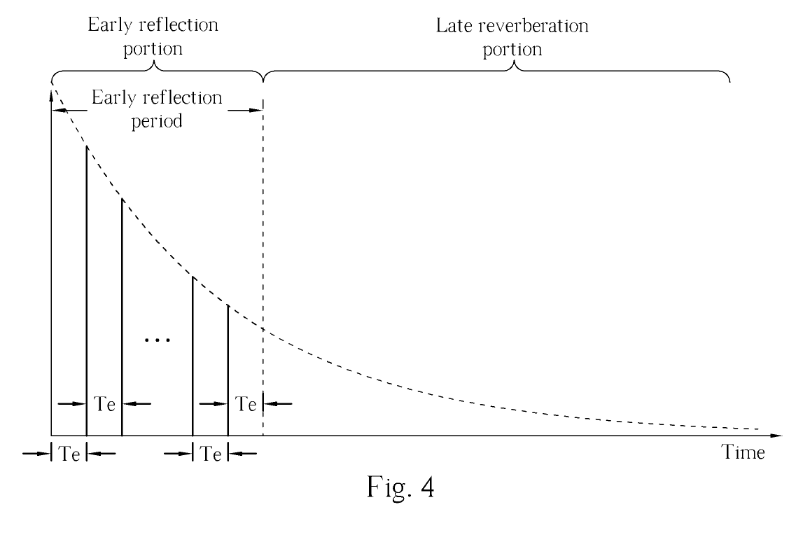

Please refer to FIG. 4, which shows the time-domain impulse response of the delay module 12, wherein the input signal Si is the input of the delay module 12, and the signal Sd is the output of the delay module 12. The horizontal axis of FIG. 4 represents time, and the vertical axis represents the magnitude of the response. As shown in FIG. 4, the delay module 12 is used to generate the delay signals, which have a delay time equal to an integer multiple of the echo interval Te, in the early reflection portion of the audio reverberation effect. When changing the length of the early reflection period, the quantity of the echo intervals covered in the early reflection period is changed as well, and thus the present invention can adaptively adjust the quantity of delays in the delay module 12. Furthermore, different delays are coupled with different multipliers, which have different signal decay factors, wherein the delay signal with a longer delay time will be multiplied by a bigger decay factor.

Please refer to FIG. 3 again. After passing through the low pass filter 14, the signal Sd, which is generated by the delay module 12, forms the early reflection portion, and then the low-pass-filtered signal Sd is processed by the late reverberation module 16 to form the late reverberation portion. The present invention can use any late reverberation algorithm to generate the late reverberation effect. In FIG. 3, the late reverberation module 16 used in the present invention has four parallel comb filters 24A to 24D, and each comb filter has a delay coupled with a multiplier to form a feedback comb filter structure, wherein the delay times of the delays in each comb filter are different from each other. In the preferred embodiment, the ratio between the longest and the shortest delay time is equal to or less than 1.5, the shortest delay time can be equal to the length of the early reflection period, and the present invention defines the ratio of three other delay times to the shortest delay time as (1+0.5/3), (1+1/3), and 1.5. In other words, the delays of these four comb filters 24A to 24D have delay times T, (1+0.5/3)T, (1+1/3)T, and 1.5 T respectively. Similarly, T is adaptively determined according to the length of the early reflection period. The multipliers in the different comb filters have different signal decay factors as well. The present invention defines the decay factor, g(i), of every multiplier according to the equation g(i)=10^{(-3×m(i)×Ts/Tr)}, where i is from 1 to n (where in this embodiment, n is 4), wherein, m(i) corresponds to the length of the delay line, Ts is the sample time interval of the audio signal, and Tr is reverb time.

After being signal-processed through the delay module 12, the low pass filter 14, and the four comb filters 24A to 24D, the output signals of each signal processing stage will be summed up by the adder module 18 to generate the output signal Sout, which has the audio reverberation effect.

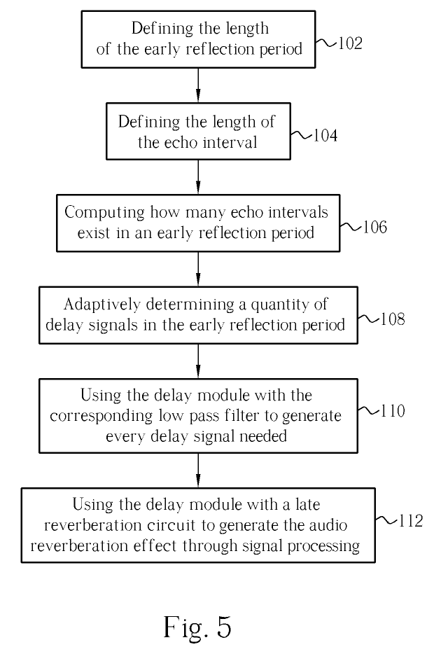

Overall, the method of the present invention for designing and implementing the audio reverberation effect circuit is shown in the flow chart of FIG. 5. Please refer to FIG. 5 in combination with FIG. 3. the flow chart of FIG. 5 includes the following steps:

Step 102: Defining the length of the early reflection period. When simulating an audio reverberation effect in a specified space, the length of the early reflection period is determined according to the factors comprising: the size and shape of the specified space, reflection characteristics of the wall, positions of the source and destination, and so on.

Step 104: Defining the length of the echo interval. As described above, according to a study of the present invention, the echo interval is defined as 8 milliseconds in the preferred embodiment of the present invention.

Step 106: Computing how many echo interval intervals are covered in an early reflection portion.

Step 108: Adaptively determining a quantity of delay signals in the early reflection period according to the computation of step 106. In the preferred embodiment of the present invention, the quantity of the delay signals is equal to the quantity of echo intervals covered in the early reflection portion, and each delay signal and its adjacent signal have a delay time interval equal to the echo interval.

Step 110: Using the delay module with the corresponding low pass filter to generate every delay signal needed.

Step 112: Using the delay module with a late reverberation circuit to generate the audio reverberation effect through signal processing.

The audio circuit 10 according to the method of the present invention can be widely used in any electronic device, such as a radio, a CD player, a DVD player, a hard disk or flash memory MP3 player, a stereo, a TV, or a multi-media computer (such as building the audio circuit into a sound card or into the sound chipset of the motherboard), and so on. Every module, delay, and multiplier of the audio circuit 10 can be implemented in various combinations of software, firmware or hardware. For example, the audio circuit 10 can be implemented by using a single signal-processing chip, wherein every module, delay, and multiplier of the audio circuit 10 can be achieved by the signal-processing chip with proper firmware. Alternately, when the audio circuit 10 is built in a computer, the central processing unit of the computer can execute the steps in software to generate the audio reverberation effect.

In contrast to the prior art, the present invention uses a simple structure to achieve the audio reverberation effect, while reducing the cost of the audio reverberation effect, simplifying the computation, decreasing the computing and memory requirements, and improving the efficiency of the implementation of the audio reverberation effect. According to an experiment, the present invention not only provides a good quality audio reverberation effect, but also prevents coloration in the audio reverberation effect.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for generating an audio reverberation effect, producing an output signal with the audio reverberation effect according to an input signal, the method comprising:
defining an early reflection period;
defining a constant echo interval;
computing a quantity of echo intervals for the early reflection period;
generating a plurality of delay signals, which are delay signals of the input signal, wherein each delay signal and its adjacent delay signal have a delay time equal to the echo interval, and a quantity of the delay signals is determined according to the quantity of echo intervals; and
generating the output signal according to a sum of the input signal and the delay signals.

2. The method of claim 1 wherein the method simulates a movement of the input signal from a source in a specified space to a destination, wherein the output signal corresponds to signals received at the destination; the method further comprising:
computing a length of the early reflection period according to factors comprising: a size of the specified space, reflection characteristics of walls of the specified space, and positions of the source and the destination.

3. The method of claim 1 wherein the echo interval is equal to or less than 10 milliseconds (ms).

4. The method of claim 1 wherein when generating the output signal according to the sum of the input signal and the delay signals, the sum of the delay signals is processed through a low-pass filter for generating the output signal.

5. The method of claim 1 further comprising:
comb filtering the sum of the delay signals for generating a late reverberation signal; and
generating the output signal according to the input signal, the delay signals, and the late reverberation signal.

6. The method of claim 5 wherein when performing comb filtering, the late reverberation signal is delayed for at least one default time period after the input signal, and the default time period is equal to the early reflection period.

7. An audio circuit for generating an audio reverberation effect, producing an output signal with the audio reverberation effect according to an input signal, the audio circuit comprising:
a delay module for generating a plurality of delay signals, each delay signal and its adjacent delay signal having a delay time equal to a constant echo interval, wherein a quantity of the delay signals is determined according to a result of computing a quantity of echo intervals in an early reflection period; and
an adder module for generating the output signal according to a sum of the input signal and the delay signals.

8. The audio circuit of claim 7 wherein the echo interval is equal to or less than 10 milliseconds (ms).

9. The audio circuit of claim 7 further comprising:
a low-pass filter electrically coupled between the delay module and the adder module for low-pass filtering of the delay signals.

10. The audio circuit of claim 7 further comprising:
a late reverberation module which comb filters the summation of the delay signals to generate a late reverberation signal; wherein the adder module generates the output signal according to the input signal, the late reverberation signal, and the delay signals.

11. The audio circuit of claim 10 wherein the late reverberation module has a plurality of comb filters to delay the late reverberation signal for at least one default time period after the input signal, where the default time period is equal to the early reflection period.

12. The audio circuit of claim 7 wherein the delay module comprises a serial plurality of delays, each delay delaying a signal for one echo interval.
